(19) United States
(12) Patent Application Publication
(10) Pub. No.: US 2026/0351503 A1
(43) Pub. Date: Nov. 5, 2026

(54) METHOD FOR REDUCED-BOUNCE SWITCHING OF AN ELECTROMECHANICAL SWITCHING ELEMENT

(71) Applicant: Phoenix Contact GmbH & Co. KG, Blomberg (DE)

(72) Inventors: Fabian WINKEL, Paderborn (DE); Peter SCHOLZ, Brakel (DE)

(21) Appl. No.: 18/997,104

(22) PCT Filed: Jul. 14, 2023
(86) PCT No.: PCT/EP2023/069681

§ 371 Date: Jan. 20, 2025

(30) Foreign Application Priority Data
Jul. 21, 2022 (LU) LU502542

(51) Int. Cl. H01H 47/02

(52) U.S. Cl. CPC H01H 47/02

(57) ABSTRACT

A method for reduced-bounce switching of an electromechanical switching element having a plurality of contacts and an armature includes: performing a specified number of switching operations in an initial phase so as to ascertain a reference value for bounce of the plurality of contacts and limit a search space for at least a time and at least a duration of a switching signal for reducing bounce. During a switching operation that follows the initial phase, a switching signal including a single pulse or a plurality of pulses, each at a specified time and each of a specified duration, is changed within the search space so as to reduce bounce of the plurality of contacts by deceleration of the armature.

### CROSS-REFERENCE TO PRIOR APPLICATIONS

This application is a U.S. National Phase application under 35 U.S.C. § 371 of International Application No. PCT/EP2023/069681, filed on Jul. 14, 2023, and claims benefit to Luxembourg Patent Application No. LU 502542, filed on Jul. 21, 2022. The International Application was published in German on Jan. 25, 2024 as WO/2024/017795 under PCT Article 21(2).

### FIELD

The disclosure relates to a method for reduced-bounce switching of an electromechanical switching element.

### BACKGROUND

An electromechanical switching element such as a relay can be switched in a gentle and thus lifetime-increasing manner by special actuation of the coil. In normal circumstances, the relay circuit is permanently switched on or off with a constant voltage, which can lead to the contacts bouncing after first meeting, i.e. repeatedly meeting in a jerky manner in the sense of a rebound, and being repelled from one another again on account of the jerky meeting, which can lead to unnecessary stress of the contact and thus possibly to a longer switching duration and reduced lifetime.

Methods are already known for reducing the bounce. For example, the bounce can be reduced by controlling the magnetic flux. For this purpose, only electrical measured variables are used and evaluated using a microcontroller 20. No additional sensors are required. Alternatively, the supply voltage signal can be changed, in the switching processes, on the basis of a plurality of parameters which are selected by an optimizer in such a way that the bounce is reduced, such as disclosed in WO 2017/163114 A1, which describes a use in the field of consumer goods.

In an embodiment, the present solution provides a method for reduced-bounce switching of an electromechanical switching element having a plurality of contacts and an armature, the method comprising: performing a specified number of switching operations in an initial phase so as to ascertain a reference value for bounce of the plurality of contacts and limit a search space for at least a time and at least a duration of a switching signal for reducing bounce, wherein, during a switching operation that follows the initial phase, a switching signal comprising a single pulse or a plurality of pulses, each at a specified time and each of a specified duration, is changed within the search space so as to reduce bounce of the plurality of contacts by deceleration of the armature.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows a schematic view of a relay having a three-pole changeover contact according to a general embodiment.

FIG. 2 shows a schematic view of a universal component according to an embodiment of the solution.

FIGS. 3 and 4 show graphs of a switch-on and switch-off process according to the prior art and according to an optimization according to the solution.

FIG. 5 shows a view of a course of a method according to an embodiment of the solution.

FIG. 6 shows a view of the outcome of the optimization over a plurality of iterations according to an embodiment of the solution.

FIG. 7 shows a view of a reduction of the bounce on average, according to an embodiment of the solution.

In an embodiment, an object underlying the proposed solution is to provide an improved method for bounce-reduced switching of an electromechanical switching element. Likewise, a universal socket having an integrated microcontroller should be provided, which implements this method.

In an embodiment, the present solution provides a method for reduced-bounce switching of an electromechanical switching element, comprising a plurality of contacts and an armature, characterized in that, in a first step, a specified number of switching operations are performed in an initial phase in order to ascertain a reference value for bounce of the contacts and in order to limit a search space for at least a time and at least a duration of a switching signal for reducing bounce, wherein, during a switching operation that follows the initial phase, a switching signal in the form of a single pulse or in the form of a plurality of pulses, each at a specified time and each of a specified duration, is changed within the search space in order to reduce bounce of the contacts by deceleration of the armature.

Within the context of the present text, reducing bounce is understood to mean that a time duration over which contacts rebound and thus bounce is reduced, i.e. the contacts come into a relative rest position with respect to one another within a shorter time period. In the case of the electromechanical switching element being switched on, contacts of a mutually associated first contact pair thus come into a rest position relative to one another within a shorter time period, preferably performing fewer bounce cycles, in which rest position the electromechanical switching element is switched on and for example the contacts are in contact with one another. When the electromechanical switching element is switched off, instead contacts of another, second contact pair optionally come into a rest position relative to one another within a shorter time period, preferably performing fewer bounce cycles, in which rest position the switching element is switched off, for example in that the other contacts are now in contact with one another, but the contacts of the first contact pair are separated from one another. Thus, reducing the bounce is to be understood as a reduction in the time period over which a rebounding bounce movement at contacts of a contact pair occurs in a switching process before the desired switching state is reached and the contacts are in a corresponding rest position relative to one another.

If the switching element is for example configured as what is known as a changeover relay, then a plurality of pairs of contacts can be provided, wherein in a switched-on state the contacts of a first contact pair are in contact with one another and the contacts of another, second contact pair are not in contact with one another, and in a switched-off state, in contrast, the contacts of the first contact pair are not in contact with one another and the contacts of the other second contact pair are in contact with one another. Reducing the bounce makes it possible, both upon switching on and upon switching off, to reduce the time duration until the contacts that come into contact with one another in each case reach a defined rest position relative to one another, and thus a rebound is excluded.

In the context of an optimization, for example a time and/or a duration of one or more pulses of a switching signal can be optimized in that the time and/or the duration of the one or more pulses of the switching signal is changed within the search space determined on the basis of the reference value, and the time duration over which a bounce movement occurs is measured. Optimization can be performed according to the time duration, such that, within the meaning of reducing the bounce, such a switching signal containing one or more pulses is determined, which leads to a reduced, preferably minimum, time duration of a bounce.

In the initial phase, in particular the duration of the bounce of the contacts for a normal, non-optimized switching signal can be determined as the reference value. In an optimization phase following the initial phase, the switching signal can then be varied in order to obtain a reduced bounce. Thus, in the context of an optimization process, the switching signal is varied and the influence on the bounce is determined, such that a switching signal is determined which leads to a reduced bounce compared with the reference value. Then, in actual operation, an optimized switching signal can be used.

In one embodiment, it is provided that the initial phase is performed in an installed state of the electromechanical switching element.

In a further embodiment, it is provided that the specified time and the specified duration are ascertained by means of an optimization algorithm which is executed during the switching operation of the electromechanical switching element.

In a further embodiment, it is provided that the optimization algorithm is a combination of a bare bone and evolutionary particle swarm optimization with a density estimation.

In a further embodiment, it is provided that the following steps are carried out:
in a first step, a normal bounce and a duration of the bounce are ascertained, and the search space is generated from this,
in a second step, a specified number of combinations of times and durations is distributed in the search space, and
in a third step, the combinations are performed and the respective bounce determined, and
in a fourth step, the combinations are sorted according to their bounce, wherein the smaller the bounce the better it is assessed, and a specified number of best combinations is retained, and
in a fifth step, new combinations are defined based on one or more of the last, best combinations, and distributed in a radius therearound, wherein in the event of the best combinations exhibiting a longer bounce than the reference value, the new combinations are selected randomly in the search space, and
in a sixth step, the normal bounce is evaluated again, when a specified condition is fulfilled, and the third to sixth step are performed repeatedly.

In a further embodiment, it is provided that the condition specified in the sixth step is that a number of switching processes have already been performed.

In a further embodiment, it is provided that the switching signal is a switch-on signal or a switch-off signal of the electromechanical switching element.

Furthermore, a microcontroller is provided, in which the method is implemented as a software program, wherein the microcontroller is further configured to measure a contact signal which reflects a bounce of the contacts, and to output a switching signal at the ascertained specified time for the ascertained specified duration, as a single pulse or as a plurality of pulses at a specified time in each case for a specified duration in each case, to the electromechanical switching element connected to the microcontroller, in order to switch said switching element in a bounce-reduced manner from a first into a second switching state.

In a further embodiment it is provided that the microcontroller outputs the switching signal as a PWM switching signal.

Furthermore, a universal component is provided, comprising:
an electromechanical switching element, comprising a plurality of contacts and an armature,
a load circuit which is configured having integrated measuring technology for generating at least one contact signal, in order to detect a bounce of the contacts,
a control circuit, to which the contact signal is transmitted, and
a microcontroller that electrically contacts the control circuit and is in signal connection with the electromechanical switching element.

In a further embodiment, it is provided that the universal component is formed as a relay socket.

Further features and advantages of the solution emerge from the following description of embodiments of the solution, on the basis of the figures of the drawing, which shows details according to the solution, and from the claims. The individual features can each be implemented individually or together in any combination, in a variant of the solution.

In the following descriptions of the figures, identical elements or functions are provided with the same reference signs.

Bouncing has a negative influence on the lifetime of electromechanical switching elements such as relays and protection means, and thus also on the entire electronic system in which they are used. Reducing the bounce (gentle switching) makes it possible to significantly improve both the lifetime and also the reliability of the electromechanical switching element, which in turn leads to economic and ecological benefits. Furthermore, the noises in the switching process are reduced and the switching time can be shortened. The optimization of the bounce reduction is a challenge, since the bounce exhibits significant variance and often a plurality of optima are present, with respect to the parameter selection.

The proposed method is used in products with electromechanical switching elements which comprise a plurality of contacts 7a, 7b, 7c and an armature 5. In particular, electromechanical switching elements of the solution are installed in universal sockets which are used e.g. in industrial automation, in HV DC switches (high voltage direct current transfer switches), or also in charging columns for electric vehicles, etc. The electromechanical switching elements used here generally cannot be configured directly after production or based on one or more reference components, since depending on the use scenario, i.e. the type of switching element, control voltage, installation position, installation site, etc., different influences act, which can lead to changed properties of the switching properties of the switching element, e.g. to bouncing. Therefore, according to the solution, a bounce reduction is carried out directly at the installation site. That is to say that the method for reducing bounce and the optimization are performed in the universal component. Both measuring technology and a microcontroller are required for this purpose.

In the following, reference is made only to a relay of an electromechanical switching element 10. However, the method can also be used for other electromechanical switching elements which may be subject to bounce, e.g. protective elements.

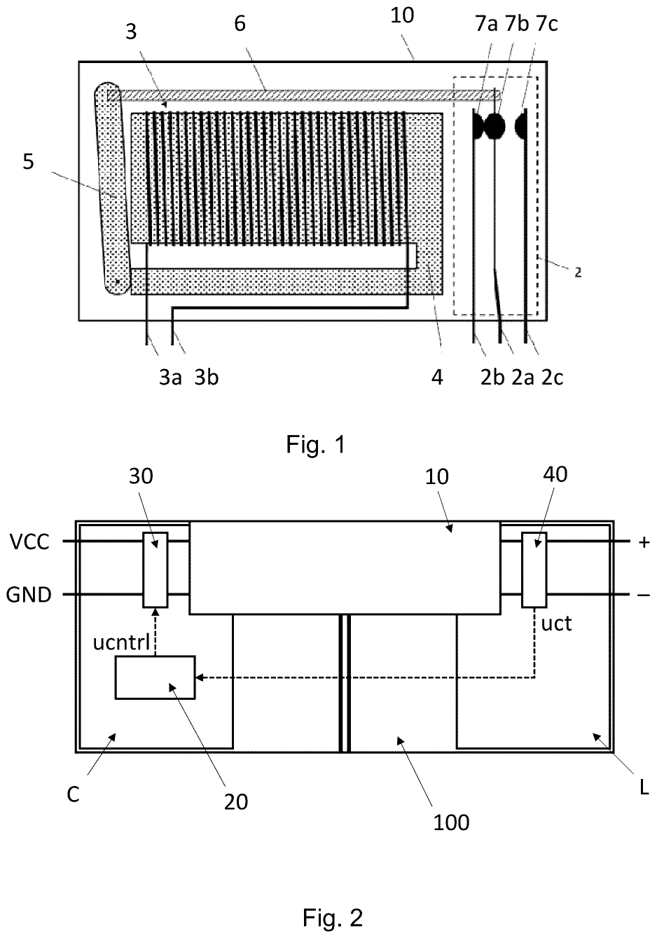

The bounce of the contacts of a relay is dependent on the movement of the components of the relay, in particular the armature 5, actuation arm and the contacts, as shown in FIG. 1, which is a schematic view of a three-pole changeover contact 2 according to a general embodiment. In the present case, the changeover contact 2 is in this case merely by way of example a part of an electromechanical switching element 10 or changeover relay.

In this case, the electromechanical switching element 10 comprises three connections which are associated with the changeover contact 2 and which are referred to in the following, according to the usual convention, as a COM connection (“common”) 2a, NC connection 2b (normally closed), and NO connection 2c (normally open). Furthermore, the electromechanical switching element 10 comprises two relay coil connections 3a and 3b, via which a relay coil 3, also referred to for short as a coil 3, of the electromechanical switching element 10 can be energized. The relay coil 3 builds up a magnetic field via the current flow, which magnetic field is guided in a magnetic core 4 and exerts a force on a movable relay armature 5, also referred to for short as an armature 5, which in turn causes a movement, via a slider 6, of one or more contact elements or contact pills 7a, 7b, 7c associated with the respective connections 2a, 2b, 2c. For example, in the present case, which is merely by way of example, in the event of a current flow through the coil 3 the COM contact pill 7a is connected to the NO contact pill 7c. If the current flow through the coil 3 is interrupted, the contact pills 7a, 7b, 7c are moved back into their original position, e.g. on account of a corresponding spring preload of the COM contact element 7a, i.e. in the present case the COM contact pill 7a contacts the NC contact pill 7b. In addition to the embodiment shown here, in which a changeover contact 2 is part of an electromechanical switching element 10, the changeover contact 2 of the type in question can, however, also be integrated in other devices, such as a changeover switch.

The movement is brought about upon switch-on (first switching state) of the electromechanical switching element 10, i.e. by a supply voltage being applied to the coil 3. The supply voltage draws the armature 5 to the coil 3. Upon switch-off (second switching state), the movement is brought about by a conversion of elastic deformation energy. Both upon switch-on and upon switch-off, the movement can be influenced with suitable switching. Upon switch-on, the acceleration of the armature 5 can be interrupted by cutting the supply voltage, and upon switch-off a force can be generated which acts counter to the movement direction of the armature 5. In this case, the technical challenge is that of optimizing the switching signal to bounce reduction.

In order to achieve the aim of the solution, in a first step S1, in an initial phase a specified number of switching operations are performed, in order to ascertain a reference value for a bounce of the contacts 7a, 7b, 7c, and in order to delimit a search space for at least a time t and at least a duration d of a switching signal ucntrl for bounce reduction, as described in more detail below. The initial phase is already performed in the installed state of the electromechanical switching element 10.

During a switching operation following the initial phase, for improved bounce reduction the switching signal ucntrl, which is preferably the switch-on signal, since bounce should be prevented here as far as possible, is changed at a certain time t for a certain duration d. Thus, during a switching operation, a single or a plurality of (voltage) pulse(s) is generated, in order to reduce the bounce of the contacts 7a, 7b, 7c, in that the armature 5 is braked. Each pulse is generated at a certain time t, and in this case has a certain duration d. In this case, the pulse or the pulses can be a complete switch-off (in the case of the switch-on signal) or switch-on (in the case of the switch-off signal) of the signal, i.e. can extend to the respective maximum voltage or minimum voltage (in general 0) ucoil, or be reduced or increase only by a specified value.

Advantageously, an optimization algorithm is used in order to ascertain the specified time t and the specified duration d of the switching signal ucntrl for bounce reduction. The optimization algorithm is executed during the switching operation of the electromechanical switching element 10. That is to say that the optimization algorithm determines the optimum coil signal form (switching signal, control voltage ucntrl), in order to reduce the bounce. For this purpose, in one embodiment measuring technology is used to obtain the information required for the gentle switching and the optimization algorithm. In this case, the required contact signal uct can be transmitted to the control circuit C in a manner galvanically separated from the load circuit L.

By means of an optimizer, t and d can be selected such that the bounce is reduced. In the context of the solution, for this purpose a particle swarm optimization (PSO) is performed. Specifically, the advantages of a bare bone PSO and an evolutionary PSO are combined in order to expand a density estimation. Other optimizers are also conceivable, however, provided they can be configured sufficiently flexibly for the characteristics of the switching of the electromechanical switching element 10 used. In contrast to the proposed PSO algorithm, the run-to-run algorithm described in the prior art has disadvantages with respect to this flexibility. Advantages of using a PSO algorithm are that this is robust against noise, the optimum can be found even in the case of a plurality of local optima, and less computational outlay is required. This is important in particular since the optimization including the initial phase takes place in application, i.e. after or during production. The longer and more frequently the electromechanical switching element 10 is used, the better the bounce reduction, since the optimization then provides ever better results.

In the context of the illustration of the solution, a two-point controller is used, i.e. either full voltage or no voltage is applied, wherein other controllers can also be used, which have any desired number of discrete starting states or one continuous starting state.

The method requires a plurality of components, which are shown by way of example as universal components 100 in FIG. 2. The components can be divided into the load side L and contact side C, and the two are connected to one another via the electromechanical switching element 10. A galvanic separation of the two sides is shown by way of example in FIG. 2, but is required only depending on the application. The control side comprises at least 2 connections, a supply voltage or switching voltage VCC and a ground potential or reference potential GND. Alternatively, two separate signals for supply and for switching can also be used. The supply voltage VCC is controlled via a circuit 30 by a microcontroller 20 with the switching signal ucntrl. The switching signal ucntrl can also be supplied to the microcontroller 20 externally. At least two connections (+) and (−) are available on the contact side, which connections can be contacted via the electromechanical switching element 10. A measuring sensor means 40 is introduced therebetween, by means of which the contact monitoring signal uct can be generated. This signal can be transmitted to the microcontroller in a galvanically separated manner, but a direct infeed or transmission is also conceivable. The contact monitoring signal uct can, by way of example, assume different voltage levels for three switching states:
the COM connection 2a skims over, no connection to NC connection 2b or NO connection 2c;
COM connection 2a and NO connection 2c are contacted, half the supply voltage is applied;
COM connection 2a and NC connection 2b are contacted, ground potential is applied.

For the applications according to the solution, said contact signal must be generated by a circuit that is galvanically separated from the electromechanical switching element 10 and the control circuit C, as indicated in FIG. 2. Alternatively thereto, another measurement technology is also possible for determining the contact signal uct.

As already mentioned, a microcontroller 20 is required, which can generate the control voltage ucntrl as single or multiple pulses e.g. in the form of a PWM signal (pulse width modulated signal), can measure the contact monitoring signal uct, and can execute an optimization algorithm such as a PSO (particle swarm optimization).

The core concept of the solution is that of changing a change in the switching signal, i.e. the control signal ucntrl, at a specific time t for a short duration d during a switching process, in order to influence the movement of the armature 5 and thus reduce the bounce. This can take place once or multiple times.

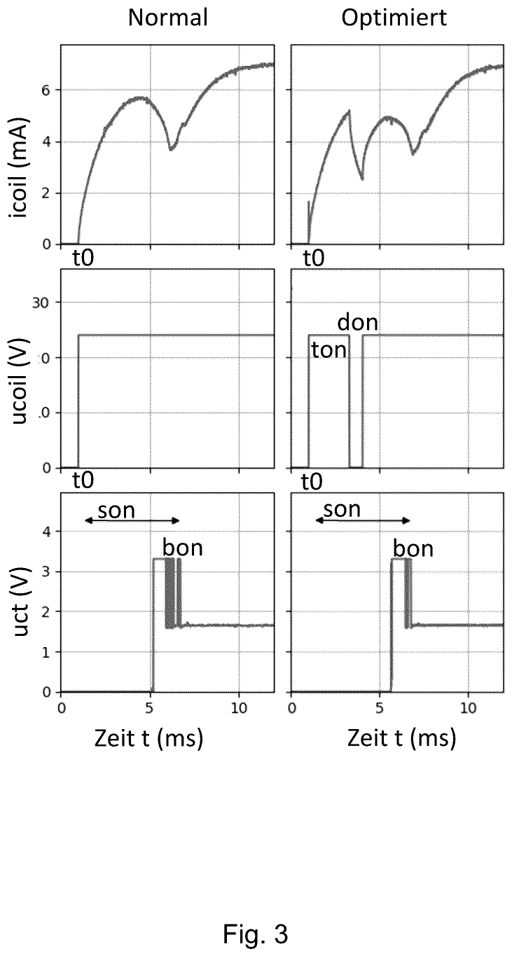

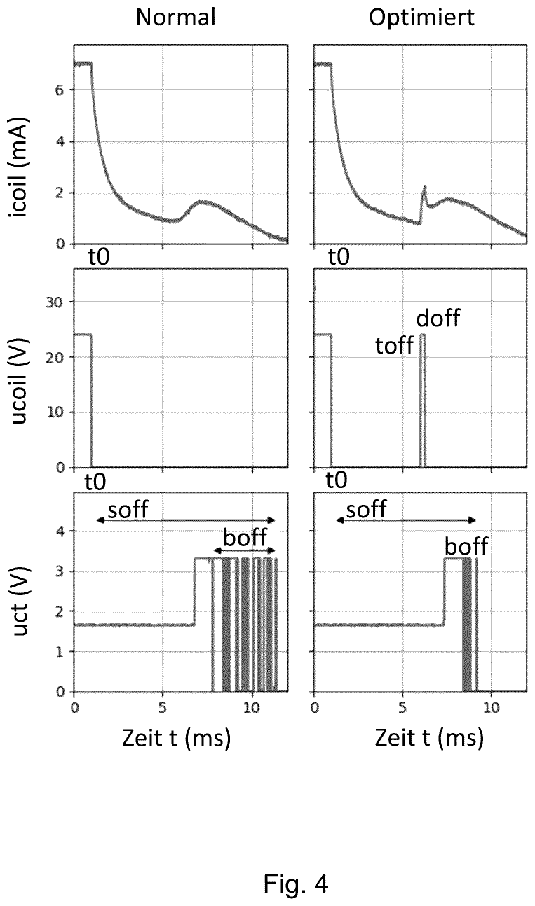

FIGS. 3 and 4 show the measured values for a normal switching cycle in the left-hand column “normal” and for a switching process optimized according to the proposed method “optimized” in the right-hand column. The switching operation starts at time to, at which the coil voltage is switched on upon switch-on and is correspondingly switched off upon switch-off. In both switching operations, after the time to the coil voltages are constant. The armature movement of the electromechanical switching element 10 is visible at the drop in the coil current icoil upon switch-on from approximately 5 ms, upon switch-off by the induced voltage at approximately 6 ms. The armature movement results in a change in the contacting of COM 2a; initially a short flight phase is visible, which transitions into a bounce bon (normal) and boff (normal) of the contacts. The switching process finally ends with a change of the switching state (on or off).

The mode of operation of the bounce reduction is explained with reference to the right-hand column of FIGS. 3 and 4. The optimized switching processes differ from the normal switching processes in that the coil voltage ucoil is change at a specific time ton or toff for a specific duration don or doff, i.e. in this embodiment is implemented as a single pulse. As a result, the coil current icoil is influenced, which drops upon switch-on (FIG. 3) and increases upon switch-off (FIG. 4), such that the armature 5 is braked in its respective acceleration. In this way, the duration of the bounce bon or boff is significantly reduced, both upon switch-on and upon switch-off. In addition, the switching duration soff upon switch-off can be reduced, in this embodiment no significant change can be observed upon switch-on son.

In principle, the pulse or pulses occur as far as possible during the armature movement, in particular shortly before the current drop/increase icoil, i.e. (shortly) before reaching the target position of the armature 5 in the switch-on or switch-off process. For reducing the bounce of the contacts 7a, 7b, 7c, the selection of the combination of the variables t and d is decisive, wherein t must be smaller than the local minimum/maximum and d may at most correspond to the time constant of the coil, since the pulse is otherwise its own switching process. Since the current drop icoil is dependent on the use and the ambient conditions prevailing there, a separate optimization at the site of use must be performed for each electromechanical switching element 10. For this purpose, an optimization algorithm can be used. This is executed in a controller, e.g. a microcontroller 20, which can be integrated, together with the electromechanical switching element 10, in a universal component (relay socket). Thus, each universal component 100 comprises a microcontroller 20 which performs the optimization and calculates the optimal parameters t and d for the electromechanical switching element, in this embodiment the electromechanical switching element 10. This is advantageous since the exact use and the ambient conditions in which the electromechanical switching element 10 is used is generally not known in advance.

In one embodiment, for each usage scenario of the electromechanical switching element 10, i.e. relay type, control voltage, installation site, etc. it is possible to ascertain in advance the specified time t and the specified duration d for each pulse, for bounce reduction (by measurements of a sample or simulation), and the ascertained values are used as starting values for the initial phase, to be executed on site, or a further optimization upon each switching, in the final application (“best guess”).

As already described, in one embodiment a PSO (particle swarm optimization) is performed, in order to ascertain the parameters t and d. Specifically, the advantages of a bare bone PSO and an evolutionary PSO are combined and expanded by a density estimation. Therefore, it is not proposed, as in the prior art, to use a run-to-run optimization.

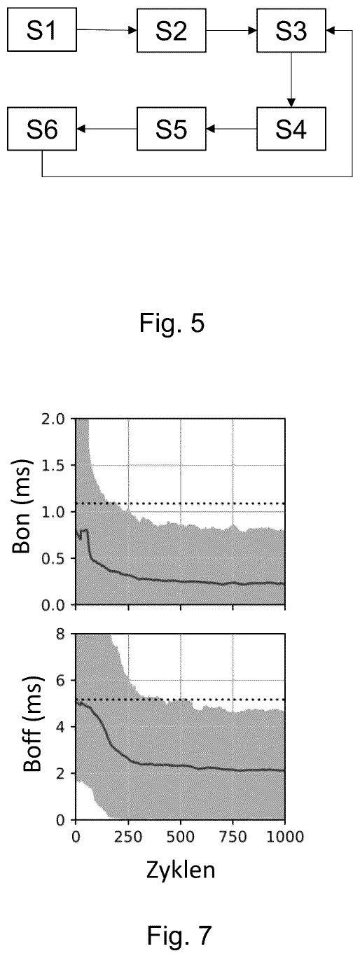

The functional design of the PSO algorithm used is shown schematically in FIG. 5, by which the two parameters t and d are optimized. The coil voltage ucoil and the coil current icoil can optionally be measured, but are not required for executing the algorithm.

The algorithm requires only the contact monitoring signal uct provided by the load circuit L, in order to determine the current state of the armature 5.

The algorithm is divided into six partial steps:

Step S1: Initial phase, which is performed dafter installation of the electromechanical switching element 10, in order to ascertain a reference value for a bounce of the contacts 7a, 7b, 7c and in order to define a search space for at least one time t and at least one duration d of a switching signal ucntrl for bounce reduction. For this purpose, tmax and dmax are determined, wherein the time tmax corresponds to the latest time at which the change is started, and dmax corresponds to the time constant of the coil. Furthermore, a reference value bnormal for the bounce without optimization (normal bounce) is determined.

Step S2 (initialization of the algorithm): Here, n (n is the number of the combinations) combinations are distributed equidistantly. Subsequently, n combinations of the sought parameters t and d are distributed equidistantly in the search space. If it is not possible to distribute n combinations, then the remaining combinations are distributed randomly in the search space.

Step 3 (iterative part of the algorithm): Here, the combinations are implemented and the actual bounce b of the contacts 7a, 7b, 7c is determined.

Step 4: Here, the best m % combinations are retained: The combinations are sorted according to their bounce b and only the m % (m is a specified numerical value) of the combinations are retained, the remainder are discarded. This procedure is inspired by the evolutionary particle swarm optimization. The best combinations are implemented again in a following iteration, in order to ensure that the bounce reduction is reproducible.

Step S5: Here, the new combinations are defined: The new combinations are determined on the basis of the best combinations. For this purpose, one of the latter is selected as the source, and a radius is calculated as the average distance from the k (k is a specified number) next combinations. Subsequently, the new combination is selected in a randomly normally distributed manner, in this radius.

Step S6: Here, after a specified number of iterations or switching processes bnormal is reevaluated. In order to ensure that the bounce b is reduced and it is not the case that e.g. a new electromechanical switching element 10 with different characteristics has been installed, it is necessary for an update of bnormal to be performed regularly (after a specified number of iterations or switching processes). If one of the best combinations does not cause a reduction, then the new combinations are distributed randomly in the search space. This procedure allows for new exploration of the search space if the behavior of the relay changes spontaneously.

Since the algorithm is executed in a loop, after each step S6 the steps S3 to S6 are repeated. If step S6 is not executed, since the necessary number of iterations has not yet been reached, steps S3 to S6 are also executed. For example, a specified number of iterations of a frequently used electromechanical switching element 10 may be 200, wherein the specified number of iterations is dependent on the usage scenario, in particular on the frequency of the switching processes.

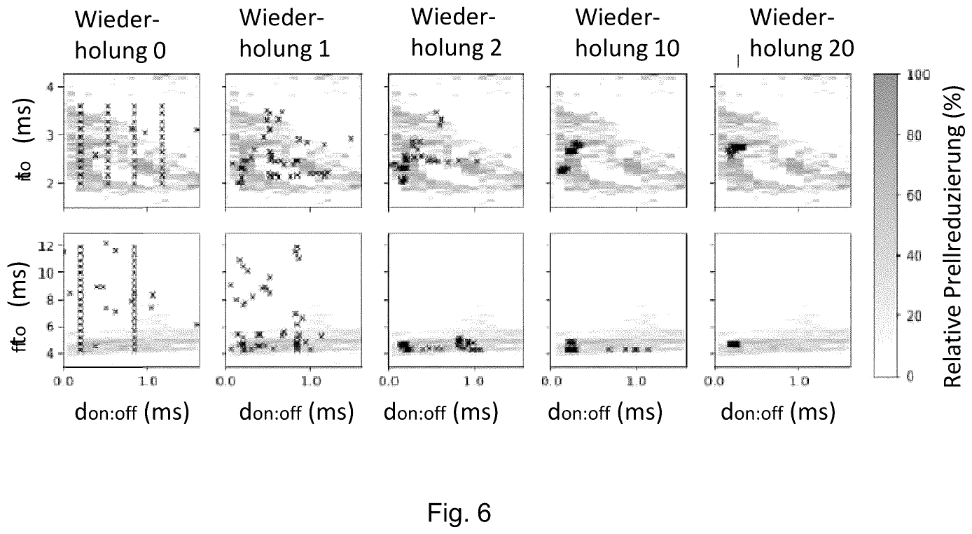

FIG. 6 shows the mode of operation of the described algorithm, as ascertained in an actual calculation. Overall ten graphs can be seen, in the top row for switch-on, in the bottom for switch-off. The individual columns specify the number of iterations shown (here 0, 1, 2, 10 and 20), wherein iterations therebetween are omitted for the sake of clarity. The time t (ms) is plotted on the y-axis, and the duration d (ms) on the x-axis. The background is colored depending on the relative reduction of the bounce; the scale is specified on the right-hand side. All possible combinations were implemented multiple times, and the bounce determined as an average value. For visual reasons, only improvements are visible, impairments correspond visually to an improvement of 0%. The combinations are marked by crosses. In the zeroth iteration (iteration 0), it can be seen that the combinations have been distributed equidistantly in the search space; some have been selected at random. In the first iteration, the combinations were determined for the first time after step S5 of the algorithm. It can be seen that the combinations become compressed in the regions having greater bounce reduction. The second iteration (iteration 2) shows the continuation of this behavior, wherein the combinations slowly converge towards maximum bounce reduction. In the tenth iteration (iteration 10) the combinations are already significantly compressed around the local maxima, wherein a plurality of maxima can be explored simultaneously. Finally it can be seen in the last iteration (iteration 20) that the respective maximum bounce reduction has been found successfully.

FIG. 7 shows the average reduction of the bounce of 48 relays for switching on (top) and switching off (bottom) in the first 1000 switching processes (cycles). In this case, both the average value and the 90% confidence interval are shown. The normal bounce bnormal serves as a reference, as a dashed line. It can be seen from the average value that upon switch-on the bounce can be reduced by 79% and upon switch-off by 58%, and in this case the algorithm converges after approximately 250 switching processes. With the convergence, the range of the 90% confidence interval also drops below the threshold of the normal bounce bnormal.

As already mentioned, for implementing the method a microcontroller 20 is required. The proposed method is implemented in said microcontroller as a software program. The microcontroller 20 is further configured to measure a contact signal uct, which reflects a bounce of the contacts 7a, 7b, 7c of the electromechanical switching element 10. It is also configured to output a switching signal ucntrl at the ascertained specified time t for the ascertained specified duration d as a single pulse or as a plurality of pulses at a specified time t in each case for a specified duration d in each case, to the electromechanical switching element 10 connected to the microcontroller 20, in order to switch said switching element in a reduced-bounce manner from a first into a second switching state (switching on or switching off).

In one embodiment, the microcontroller 20 outputs the switching signal ucntrl as a PWM switching signal ucntrl.

Furthermore, a universal component is proposed, which comprises an electromechanical switching element 10 having a plurality of contacts 7a, 7b, 7c and an armature 5, a load circuit L which is configured having integrated measuring technology for generating at least one contact signal uct, in order to detect a bounce of the contacts 7a, 7b, 7c of the electromechanical switching element 10, a control circuit C to which the contact signal uct is transmitted, preferably in a manner galvanically separated from the load circuit L, and a microcontroller 20 that electrically contacts the control circuit C and is in signal connection with the electromechanical switching element 10. In this case, the universal component is advantageously a relay socket, in which all the components are integrated.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention or solution refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

2 changeover contact
2a COM connection
2b NC connection
2c NO connection
3 relay coil
3a, 3b relay coil connections
4 magnetic core
5 relay armature
6 slider
7a-7c contact elements
10 electromechanical switching element
20 microcontroller
30 switching circuit for the control voltage ucntrl
40 sensor means for the contact monitoring signal uct
100 universal component (relay socket)
C control circuit
L load circuit
uct contact monitoring signal
ucntrl control voltage
icoil coil current
ucoil coil voltage
bon, boff duration of the bounce
son, soff switching duration

1: A method for reduced-bounce switching of an electromechanical switching element having a plurality of contacts and an armature, the method comprising:
performing a specified number of switching operations in an initial phase so as to ascertain a reference value for bounce of the plurality of contacts and limit a search space for at least a time and at least a duration of a switching signal for reducing bounce,
wherein,
during a switching operation that follows the initial phase, a switching signal comprising a single pulse or a plurality of pulses, each at a specified time and each of a specified duration, is changed within the search space so as to reduce bounce of the plurality of contacts by deceleration of the armature.

2: The method of claim 1, wherein the initial phase is performed in an installed state of the electromechanical switching element.

3: The method of claim 1, wherein the specified time and the specified duration are ascertained by an optimization algorithm which is executed during the switching operation of the electromechanical switching element.

4: The method of claim 3, wherein the optimization algorithm comprises a combination of a bare bone and evolutionary particle swarm optimization with a density estimation.

5: The method of claim 1, further comprising. in order:
ascertaining a normal bounce and a duration of the normal bounce, and the search space generated therefrom;
distributing in the search space a specified number of combinations of times and durations;
performing the combinations and determining the respective bounce determined;
sorting the combinations according to their bounce, and retaining a specified number of best combinations;
defining new combinations based on one or more of the last, best combinations, and distributed in a radius therearound, and, if the best combinations exhibiting a longer bounce than the reference value, selecting randomly the new combinations in the search space; and
evaluating the normal bounce again upon fulfilling a specified condition,
wherein and the performing, sorting, and defining are performed repeatedly.

6: The method of claim 5, wherein the specified condition is that a number of switching processes has already been carried out.

7: The method of claim 1, wherein the switching signal comprises a switch-on signal or a switch-off signal of the electromechanical switching element.

8: A microcontroller implementing the method of claim 1 as a software program, the microcontroller being configured to:
measure a contact signal representative of a bounce of the plurality contacts; and
output a switching signal at the ascertained specified time for the ascertained specified duration, as a single pulse or as a plurality of pulses at a specified time in each case for a specified duration in each case, to the electromechanical switching element connected to the microcontroller, so as to switch the electromechanical switching element in a bounce-reduced manner from a first switching state into a second switching state.

9: The microcontroller of claim 7, wherein the microcontroller is configured to output the switching signal as a PWM switching signal.

10: A universal component, comprising:
an electromechanical switching element comprising a plurality of contacts and an armature;
a load circuit having integrated measuring technology configured to generate at least one contact signal so as to acquire a bounce of the plurality of contacts;
a control circuit to which the contact signal is transmitted; and
the microcontroller of claim 8, the microcontroller being configured to electrically contacts the control circuit and being in signal connection with the electromechanical switching element.

11: The universal component of claim 10, which is formed as a relay socket.
